(19) United States
(12) Patent Application Publication
(10) Pub. No.: US 2015/0296612 A1
(43) Pub. Date: Oct. 15, 2015

(54) Composite Body Having a Decorative Surface, an Electrically Conductive Structure and an Electronic Circuit

(71) Applicant: Schoeller Technocell GmbH & Co. KG, Osnabruck (DE)

(72) Inventors: Rainer Gumbiowski, Wallenhorst (DE); Wolfgang Schmidt, Georgsmarienhutte (DE)

(21) Appl. No.: 14/678,527

(22) Filed: Apr. 3, 2015

(30) Foreign Application Priority Data
Apr. 10, 2014 (DE) 202014003058.8

(51) Int. Cl. H05K 1/02; H05K 1/11; H05K 1/09; B05D 3/00

(52) U.S. Cl. CPC H05K 1/0298; B05D 3/007; H05K 1/115; H05K 1/09

(57) ABSTRACT

A composite body comprises a substrate (4), a first decorative paper (1) and an electrically conductive structure (2.1) which is arranged between the substrate and first decorative paper (1), wherein at least one electrical conductor (6) connects the electrically conductive structure (2.1) to an electronic circuit (5), and the first decorative paper (1) is arranged above the electrically conductive structure (2.1) in order to cover said structure.

### CROSS-REFERENCE TO RELATED APPLICATIONS

This application claims priority to German Patent Application No. 202014003058.8, filed Apr. 10, 2014, the entire contents of which are incorporated herein by reference.

### TECHNICAL FIELD OF THE INVENTION

The invention relates to a composite body comprising a substrate, an electrically conductive structure, which is connected to an electronic circuit by means of an electric conductor, and at least one decorative cover for the conductive structure.

### TECHNICAL BACKGROUND OF THE INVENTION

Decorative laminates based on decorative papers or decorative films have been used for a long time to coat, with a decorative coat, the surfaces of panels which are used for example for furniture production or for interior finishing, as coverings for walls, floors or ceilings. The decorative papers or decorative films are used in this case as a colour layer and optionally as a substrate for a decorative print. For this purpose, a decorative pattern is optionally printed on what are known as decorative base papers, which are then impregnated and lacquered. Finally, the decorative papers or decorative films thus obtained are then laminated onto a final substrate under the effect of pressure and heat. The decorative laminates thus obtained are classified as what are known as high-pressure laminates (HPL) or low-pressure laminates (LPL) depending on the pressure used during lamination.

What are known as prepregs can also be used as decorative papers or decorative films. These are produced by the unsized base paper firstly being impregnated, printed on and optionally lacquered, and then applied to a permanent substrate using a resin, an adhesive or glue under the effect of pressure and/or heat.

To produce a high-pressure laminate, the decorative paper or the decorative film is impregnated, before or after being printed on, with a synthetic resin and is compressed with one or more layers of kraft paper sheets which have been saturated in phenol resin (resin-laminated core paper), in a laminating press at a temperature of from approximately 110 to 170° C. and a pressure of from approximately 5.5 to 11 MPa. The laminate (HPL) thus created is then glued or bonded to a substrate such as HDF or chipboard.

A low-pressure laminate is produced by the decorative paper or decorative film, which has or has not been printed on and which is impregnated with a synthetic resin, being directly compressed to the substrate panel at a temperature of from approximately 160 to 200° C. and a pressure of from approximately 1.25 to 3.5 MPa. Upon compression, the resin cures completely in an irreversible manner. This complete curing not only produces the bond to the substrate, but the paper is also completely chemically and physically sealed.

Synthetic resins suitable for impregnation are the impregnation resins that are generally used in this technical field, including what are known as aminoplast resins, such as melamine formaldehyde resin and urea formaldehyde resin, and resins such as phenol formaldehyde resin, polyacrylate and styrene/acrylic acid ester copolymers. The impregnation resin can be used in an amount of from 40 to 250%, preferably from 80 to 125%, based on the mass per unit area of the decorative base paper.

The decorative printed pattern is typically applied in a gravure printing process. In particular when producing decorative patterns which are common on the market, this printing technique has the advantage of being able to print large volumes of paper at high machine speeds. However, the gravure printing process is not cost-effective when printing relatively small volumes of decorative base paper and is insufficient in terms of the printing quality of complicated patterns. Of the printing techniques which meet the requirements of flexibility and quality, ink jet printing is becoming ever more important.

To increase the print quality of decorative base papers for the ink jet printing method, said papers are coated with one or more functional layers for absorbing the ink and fixing the dyes. DE 199 16 546 A1 and EP 1 044 822 A1 describe decorative base papers of this type which can be printed on by ink jet printing.

The ink absorption layers generally contain pigments, water-soluble or water-dispersible polymers as binders, dye-fixing substances and other auxiliary agents typically used in such coats.

Besides decoratively coating the surface of substrates such as building boards or components, it is becoming increasingly important to equip such composite bodies in a functional manner, in particular to equip them with functions for switching electrical consumers.

It is known that conductive structures can also be produced on papers by means of ink jet printing. WO 2010/063222 A1 describes a paper which has a coat and to which inks containing conductive particles are applied using the inkjet printing method, and an electrically conductive structure is thus produced. The receiving layer described therein is disadvantageous, however, in that it largely closes the pores in the paper surface, and therefore the paper is not suitable for being subsequently impregnated with synthetic resins.

DE 10 2008 062809 A1 describes decorative laminate surfaces, in which a layer having an electrical function is arranged beneath a decorative layer. However, the document does not give any indication of how the electrical component embedded in the electrically insulating laminate is connected to an electrical consumer, or how other conductive connections can be established to the functional coat, for example for the supply of energy.

For this purpose, mechanical switch elements are typically inserted in holes or countersinks, and these are connected to the consumers by means of metal conductors. This approach has the drawback, however, that the decorative surface of the composite body is broken or destroyed in part and that additional operations are required for mechanically machining the substrate, for installing the switch elements and for connecting them electrically.

The requirement thus exists to equip the substrates, which are provided with a decorative surface, in a functional manner, in particular to equip them with functions for switching electrical consumers, while simultaneously maintaining the ability to impregnate the functionally equipped surface with a synthetic resin.

There is also the need to advantageously connect an electrically conductive structure to an electronic circuit in a technically simple manner, without impairing the decorative surface.

### SUMMARY OF THE INVENTION

The object of the invention is to provide a composite body having a decorative surface and an electrically conductive structure beneath the decorative surface, the electrically conductive structure not impairing the ability of a paper, which is optionally coated therewith, to be impregnated, and the electrically conductive structure having an electrical connection to an electronic circuit.

In addition, the composite body is intended to be provided in a simple and cost-effective manner using lamination processes which are common in the furniture and wood materials industries.

This object is achieved by a composite body comprising a substrate, a first decorative paper and an electrically conductive structure which is arranged between the substrate and first decorative paper, an electrical conductor connecting the electrically conductive structure to an electronic circuit, and the first decorative paper being arranged above the electrically conductive structure in order to cover said structure.

### DESCRIPTION OF PREFERRED EMBODIMENTS

Decorative paper within the meaning of the invention is any planar decorative material which can be used for decoration purposes in furniture construction or interior finishing. The term “decorative paper” used here therefore includes the standard decorative papers, prepregs and decorative films.

Suitable substrates are, for example, wood panels and fiber boards. In addition, other electrically non-conductive materials can also be used as substrates. The substrate can be either panel-shaped or a shaped body having a different shape from a panel.

The first decorative paper can be what is known as an overlay, which is largely transparent following compression. Preferably, however, use is made of a decorative paper which is produced using a decorative base paper and has high opacity once compressed to form the composite body. In this case, the conductive structure, such as one or more electrically conductive coats, and thus the arrangement and position of the at least one sensor surface formed by the electrically conductive structure is no longer visible on the surface of the finished laminate. It is also preferable for the first decorative paper having high opacity to be provided with an informative and optionally also a decorative graphic overprint. An informative overprint within the meaning of the invention is, for example, the overprint of a light bulb as a symbol for a light switch which is located at that point, or the overprint of what are known as power symbols to indicate that a particular function is switched on and off at this point. Said overprint can be produced using any printing method that can be used for decorative papers. Preferably, digital printing methods, in particular inkjet printing, are used to allow for a variable design of the printed image.

The electrically conductive structure can be printed directly onto the substrate or onto a second decorative paper which is arranged between the substrate and the first decorative paper.

Aside from the gravure printing method, which is common for producing decorative laminates, high-pressure printing methods such as flexographic printing methods are also particularly suitable as printing methods for the electrically conductive structure. Another advantageous printing method is screen printing, by means of which relatively thick coats of the conductive material can be printed and thus the conductivity of the conductive structure can be increased. Preferably, however, digital printing methods such as inkjet printing are used in this case too for printing the conductive structure. This method allows for a variable design of the conductive structure, even for individual parts.

Any material having suitable electrical conductivity can be used as the conductive material for printing the conductive structure. Electrically conductive polymers such as polyaniline or poly(3,4-ethylenedioxythiophene), the latter in particular in combination with polystyrene sulfonic acid (PEDOT:PSS), are suitable. Preferably, however, non-film-forming, particulate materials such as natural or synthetic graphite, in particular petroleum carbon black or conductive metal particles, for example of aluminium, copper or silver, are used as the conductive material for printing the conductive structures. Particle sizes of the conductive material of less than 1 μm, in particular in the range of from 10 nm to 500 nm, are preferred.

In addition to the above-mentioned first decorative paper, the composite body can contain additional decorative papers and functional layers, in particular additional overlay decorative papers, which can be coated with pigment particles, for example consisting of silicic acid or corundum (aluminium oxide) to improve the resistance to abrasion. Preferably, an overlay can be arranged on the side of the first decorative paper facing away from the substrate.

Furthermore, the composite body can also contain additional decorative papers and functional layers between the first decorative paper and the substrate. These can be, for example, additional overlay decorative papers.

During compression, the surface (visible side) of the composite body can be designed to be glossy, matte or to have any given structure by using appropriate pressure plates.

The electrical conductor, in particular a metal conductor, which connects the electrically conductive structure to an electronic circuit, can be produced from any electrically conductive material. Preferably, the conductor can be formed such that it is in direct electrical contact with the conductive structure, while a part of the conductor can penetrate the substrate at least in part.

More preferably, the electrical conductor can be formed in a plate-like manner at one end such that an underside of the plate of the electrical conductor is in direct conductive contact with the electrically conductive structure and a pin-shaped part, which is arranged substantially perpendicularly thereto, of the body penetrates the substrate at least in part.

Furthermore, the electronic circuit can comprise an evaluation device which can in particular detect a change in capacitance. For this purpose, the electronic circuit can apply an electrical signal to the electrically conductive structure or at least one electrically conductive coat. To generate the signal, the electronic circuit can have a separate power supply, for example via a battery or an accumulator. Said circuit can also be coupled to the electrical power grid.

The electrically conductive structure is more particularly a measuring electrode or sensor electrode. The electronic circuit is designed in particular to detect a change in the electric field generated by the sensor electrode. A change in the electric field is brought about in particular by introducing a conductive or non-conductive object, such as a finger of a user, into the electric field.

The electronic circuit can for example be configured to trigger an action when it is detected that a predeterminable limit value has been exceeded. For example, an action can be to open and/or close a switch to preferably activate or deactivate an electrical consumer.

The composite body according to the invention can be produced for example by means of a method comprising the following steps:

1) providing an electrically nonconductive substrate;
2) printing an electrically conductive structure onto the substrate or onto a second decorative base paper or impregnated decorative paper;

3) optionally printing a decorative and/or informative image onto a first decorative base paper or decorative paper;

4) optionally impregnating the obtained printed decorative base papers with thermally crosslinkable resin;

5) optionally applying the second, impregnated decorative paper, on which the conductive structure has been printed, onto the substrate,
6) connecting the electrically conductive structure with an electrical conductor which penetrates the substrate at least in part;
7) compressing the decorative paper(s) together with the substrate in a press at high temperature until the impregnation resin at least partly cures.

For printed decorative papers which have already been impregnated, step (4) is omitted. Step (5) is omitted if the electrically conductive coat has been applied directly to the substrate.

In a preferred embodiment of the invention, at least two impregnated decorative papers are compressed directly to a substrate according to the low-pressure printing method (LPL). At least one decorative paper saturated with a thermally crosslinkable resin can also be laminated onto the rear side of the substrate.

As an alternative to directly compressing of two decorative paper layers with a substrate according to the low-pressure printing method (LPL), as soon as the metal body has been introduced a first compression and the thermal curing can be performed, and then, once the decorative second paper (visible side) and optionally additional decorative papers is/have been applied, this/these are compressed and cured in an additional process step.

Further properties, features and advantages of the invention will be described in more detail below with reference to the drawings.

### BRIEF DESCRIPTION OF THE FIGURES

FIG. 1 shows a schematic cross section of a preferred embodiment of the composite body having an integrated conductive sensor surface for capacitive proximity sensors.

FIG. 2 shows an example of a printed electrically conductive structure having the contact points (X).

FIG. 3 shows an example of a front side of a composite body.

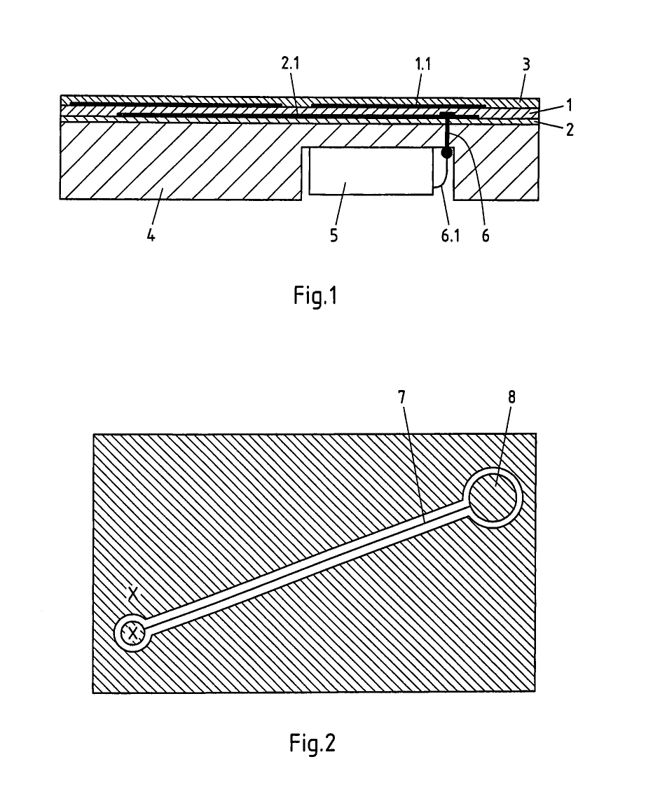

FIG. 1 is a schematic view of the construction of a composite body. A multilayer laminate containing a first decorative paper 1 impregnated with thermally crosslinkable resin and a second decorative paper 2 impregnated with thermally crosslinkable resin is applied to the visible side (front side) of the substrate 4. In this case, an electrically conductive structure 2.1 is printed on the second decorative paper 2. The first decorative paper 1 preferably has high opacity and is optionally provided with a decorative print 1.1. To improve the surface properties, such as gloss or resistance to abrasion, one or more overlays 3 can be applied to the optionally decorative first decorative paper 1.

The electrical conductor 6 in particular in the form of a metal conductor 6 is introduced in the laminate layer 1 to 3 such that a planar part of the conductor 6 is in direct electrical contact with the electrically conductive structure 2.1, which is produced by printing, of the printed second decorative paper 2, and a pin-shaped part, which is arranged substantially perpendicularly thereto, of the conductor 6 penetrates the substrate 4 at least in part. This metal conductor 6 is connected to the electronic circuit 5 by a cable 6.1 which is attached thereto.

A plurality of metal conductors 6 can be attached to a substrate 4, which conductors contact various separate or interconnected electrically conductive coats or regions of the printed electrically conductive structures 2.1 in the above-described manner.

The electrically conductive structure 2.1 forms a sensor electrode 2.1 to which an electrical signal can be applied by the electronic circuit 5. The sensor electrode 2.1 generates an electric field on the basis of the electrical signal. In particular, a voltage can be applied to the sensor electrode 2.1 and to a reference electrode (not shown), which can be at earth potential.

The electronic circuit 5 can preferably comprise an RC oscillator circuit. A circuit of this type allows for measurement of the capacitance between the sensor electrode 2.1 and an electrical earth potential. The capacitance is changed by for example a finger of a user being brought close to the active region of the sensor, which region is formed by the electric field. More particularly, the capacitance is increased. The change in capacitance influences the oscillation amplitude of the RC oscillator of the RC oscillator circuit.

This change can be compared with a predeterminable limit value using a comparison unit. If the limit value is reached or exceeded (missed), an action can preferably be triggered. For example, a switch can be opened or closed. Otherwise, no action is brought about.

The limit value can in particular correspond to a desired minimum proximity of for example a finger to the sensor electrode 2.1. A defined triggering region can be provided.

In a preferred embodiment, this monitoring electronics 5 is arranged in a recess in the rear side of the substrate 4.

FIG. 2 shows, by way of example, a printed electrically conductive structure having the contact points X. The hatched regions and the connecting line 7 have been printed on using conductive ink. Point 8 denotes a switch surface.

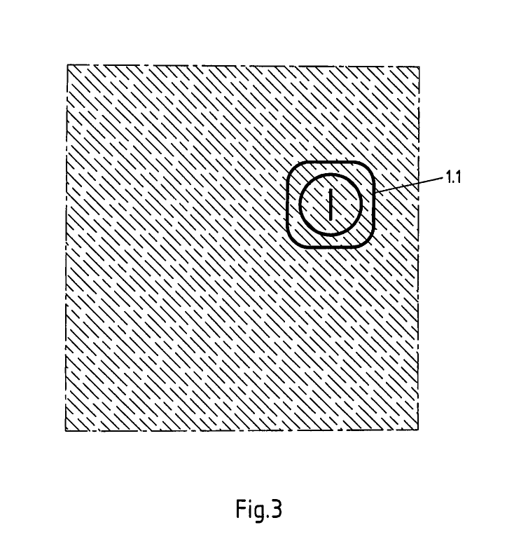

FIG. 3 shows, by way of example, a design option for the front side of the composite body. In particular, a switch surface 1.1 is marked, preferably printed, on the front side. The switch surface 1.1 is attached in particular above the electrically conductive structure. When a finger or another body part and/or an object are brought sufficiently close to the switch surface 1.1, this can be detected by an electronic circuit in the above-described manner.

A manner of producing the composite body according to the invention will be described below by way of example.

Printing the Conductive Structures

0.2 g of carboxymethyl cellulose (CMC) is dissolved in 30 g of water and 70 g of isopropanol, and 20 g of conductive carbon black VULCAN XC72R from Cabot Corporation USA is introduced into the solution while using a dissolving agitator. The obtained ink has a surface tension of 32 mN/n and a viscosity of 18 mPas. Using the obtained ink, conductive structures according to FIG. 2 were printed on IJ Dekor® TC 9653-100 decorative base paper, which can be printed on using inkjet printing, from Schoeller Technocell GmbH & Co. KG, Osnabruck using a Dimatix DMP 5000 printer. The obtained sheet area resistance R_{□} of the printed regions is R_{□}=196 Ω/□.

Printing a Decorative Surface Graphic

A decorative image as an indicator for a switch 3 was printed on a sheet of IJ Dekor® TC 9653-100 decorative base paper, which can be printed on using inkjet printing, from Schoeller Technocell using the inkjet printer EPSON® 4800 and the original inks (coloured pigment inks) from the printer manufacturer.

Saturating and Compressing the Sheets of Decorative Base Paper

To saturate the individual sheets, a solution having 52 wt. % melamine formaldehyde resin (KAURAMIN® 773 from BASF SE) in water is used, to which solution 1.6 wt. % wetting agent (Hypsersal® VXT 3797 from Surface Specialities Germany) and 0.8 wt. % MADURIT® curing agent MH 835/70 W, obtainable from Ineos Melamines, Germany, is added.

The sheets of decorative base paper are placed on the resin solution until they are completely saturated, but at least for 60 seconds, and are then completely submerged in the resin bath. Excess resin is then shaken off and the sheet is dried for 25 seconds at 130° C. Next, the sheet is again completely submerged in the resin solution, excess resin is again shaken off, and the sheet is dried at 130° C. up to a residual moisture of 6 wt. %.

Producing the Composite Body Having Integrated Sensor Surfaces

An overlay paper of the type “white 0” 65 g/m² from DUROPAL was placed on a 40×40 cm chipboard having a thickness of 22 mm, and the saturated second decorative paper, on which the conductive structures are printed, was placed on said overlay. Two 0.7×1.5 mm brass flat-headed nails were driven into the substrate panel and countersunk at the contact points, denoted by X in FIG. 2, of the sheet on which the conductive structures are printed. Once an additional overlay sheet was placed thereon, a first compression was carried out according to the LPL method for four minutes at a temperature of 140° C. The obtained composite body was then cooled in the press to 60° C.

The sheet, on which the decorative and informative graphic structures are printed and which is saturated with resin, was placed on the composite body as the second paper layer. An additional overlay sheet was also placed thereon and compressed again for four minutes at a temperature of from 140° C. using high-gloss pressure plates. The obtained composite body was then cooled in the press to 60° C.

Introducing the Evaluation Electronics

A suitable countersink was made on the side of the composite body facing away from the visible surface directly next to the position of the metal conductors in the form of nails, and a radio sensor of the MT 0.7-TX type from Edisen Sensorsysteme GmbH, Lauchhammer, Germany was inserted therein. The sensor connections are connected to the nails by soldering, the earth connection being connected to the peripheral conductive surface which is relatively large in terms of surface area, and the sensor connection being connected to the relatively small switch surface.

The composite body according to the invention meets high aesthetic requirements. By simply bringing a human finger close to the designated sensor position of the front side (visible side) of the composite body, a switch command can be triggered, while touching the other regions of the decorative surface of the composite body does not trigger a switch command.

1. A composite body comprising a substrate, a first decorative paper and an electrically conductive structure which is arranged between the substrate and first decorative paper, characterised in that at least one electrical conductor connects the electrically conductive structure to an electronic circuit, and the first decorative paper is arranged above the electrically conductive structure in order to cover said structure.

2. Composite body according to claim 1, wherein the electrically conductive structure is applied to a second decorative paper, which is arranged between the substrate and first decorative paper.

3. Composite body according to claim 1, wherein the electrically conductive structure is applied using a digital printing method.

4. Composite body according to claim 1, wherein the electrically conductive structure contains natural or synthetic graphite, petroleum carbon black and/or conductive metal particles.

5. Composite body according to claim 1, wherein an overlay is arranged on the first decorative paper.

6. Composite body according to claim 1, the electrical conductor is formed in a plate-like manner at one end, and the underside of the plate is in direct conductive contact with the electrically conductive structure.

7. Process for the manufacture of a composite body according to claim 1, comprising the following steps:
(1) providing an electrically nonconductive substrate;
(2) printing an electrically conductive structure onto the substrate or onto a second decorative base paper or impregnated decorative paper;
(2) printing an electrically conductive structure onto the substrate or onto a second decorative base paper or impregnated decorative paper;
(3) optionally printing a decorative and/or informative image onto a first decorative base paper or decorative paper;
(4) optionally impregnating the obtained printed decorative base papers with thermally crosslinkable resin;
(5) optionally applying the second, impregnated decorative paper, on which the conductive structure has been printed, onto the substrate,
(6) connecting the electrically conductive structure with an electrical conductor which penetrates the substrate at least in part;
(7) compressing the decorative paper(s) together with the substrate in a press at high temperature until the impregnation resin at least partly cures.

8. Process according to claim 7, wherein the electrically conductive structure is applied to a second decorative paper, which is arranged between the substrate and first decorative paper.

9. Process according to claim 7, wherein the electrically conductive structure is applied using a digital printing method.

10. Process according to claim 7, wherein an overlay is arranged on the first decorative paper.

11. Process according to claim 7, wherein the electrical conductor is formed in a plate-like manner at one end, and the underside of the plate is in direct conductive contact with the electrically conductive structure.
